(19) United States
(12) Patent Application Publication
(10) Pub. No.: US 2024/0431034 A1
(43) Pub. Date: Dec. 26, 2024

(54) PRINTED CIRCUIT BOARD MANUFACTURING PROCESS AND PRINTED CIRCUIT BOARD

(71) Applicant: Gebr. Schmid GmbH, Freudenstadt (DE)

(72) Inventor: Christian Schmid, Freudenstadt (DE)

(73) Assignee: Gebr. Schmid GmbH, Freudenstadt (DE)

(21) Appl. No.: 18/575,017

(22) PCT Filed: Sep. 8, 2022
(86) PCT No.: PCT/EP2022/075027

§ 371 Date: Dec. 28, 2023

(30) Foreign Application Priority Data
Sep. 8, 2021 (DE) 10 2021 209 939.4

(51) Int. Cl. H05K 3/10; C23C 18/16; C23C 18/31; C23C 28/02; C25D 5/02; C25D 5/56; G03F 7/20; H05K 1/03

(52) U.S. Cl. CPC H05K 3/107; C23C 18/1605; C23C 18/1641; C23C 18/1653; C23C 18/31; C23C 28/02; C25D 5/022; C25D 5/56; G03F 7/2002; H05K 1/0373; H05K 2203/095

(57) ABSTRACT

A method of manufacturing a printed circuit board having a metallic conductor structure that includes providing a base substrate in a film or sheet having a first substrate side and a second substrate side, which consists at least partly of an electrically non-conductive organic polymer material, covering the first substrate side with a resist, partially removing the resist, so that the first substrate side is divided into at least a first sub-area, in which the first substrate side is still covered with the resist, and into at least a second sub-area, in which the first substrate side is free of the resist, after partial removal of the resist in the at least one second sub-area, applying a plasma to the first substrate side such that the polymer material in the at least one second sub-area is removed, and thereby forming at least one elongate, channel-like recess, applying a metallization to the first substrate side, and planarizing the first substrate side, optionally with removal of the metallization in the first sub-area, and with retention of the formed at least one elongate, channel-like recess, wherein the resist is a photoresist or a resist made of a laser-removable polymer material, the resist in the first sub-area is completely or at least almost completely removed by the plasma treatment, and the resist is applied to the first substrate side in a thickness that ensures that a desired depth of the elongate channel-like recess is achieved before significant ablation of the first substrate side by the plasma in the first sub-area occurs.

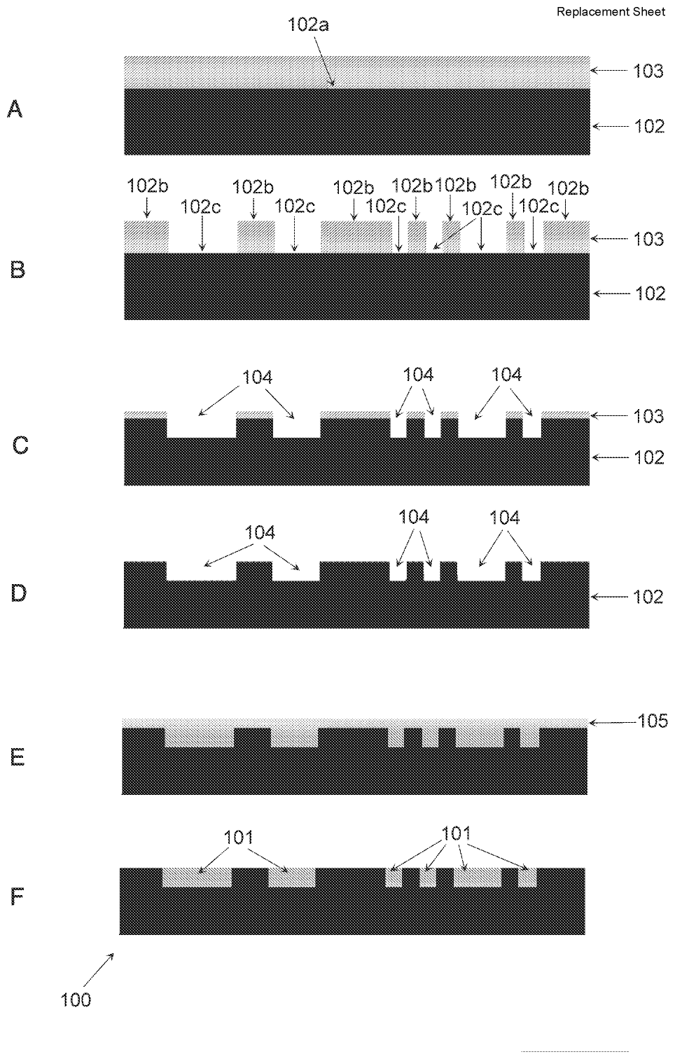

### TECHNICAL FIELD

This disclosure relates to a method of manufacturing printed circuit boards and printed circuit boards manufactured in accordance with the method.

### BACKGROUND

A printed circuit board (PCB) serves as a carrier for electronic components and ensures their electrical contacting. Almost every electronic device contains one or more printed circuit boards.

Printed circuit boards always comprise a base substrate that is electrically non-conductive and has a structure of conductor tracks (conductor structure) on at least one side of the substrate for making electrical contact with the electronic components. Generally, base substrates for printed circuit boards are made of fiber-reinforced plastic, plastic films or hard paper. The conductor tracks are usually made of a metal such as copper.

In the simplest structure, only one side of the base substrate has a conductor structure. For more complex circuits, however, more than one conductor track level is often required, in which case a multilayer board (MLB) is needed. In these examples, both sides of a carrier layer can be provided with a conductor structure, or several base substrates, each with a conductor track level, can be combined to form an MLB. In particular, base substrates provided with a conductor structure on both sides can also form a basis for multilayer structures. The conductor tracks of the different conductor track levels can be electrically connected to each other via vias. For this purpose, holes can be drilled into the base substrates and the walls of the drilled holes can be metallized.

Formation of conductor structures on a base substrate is classically carried out subtractively in a multi-stage photolithographic process using a photoresist (resist), the solubility of which in a developer solution can be influenced by radiation, in particular UV radiation. In a standard procedure, a metal layer, usually a copper layer, is formed on the base substrate and covered with a layer of photoresist. The photoresist layer can be laminated onto the metal layer, for example. The photoresist layer is then exposed to the aforementioned radiation in an exposure step, whereby sub-areas of the layer are protected from exposure to radiation by an exposure mask. Depending on the photoresist and developer solution used, after the exposure step either the exposed or unexposed sub-areas of the photoresist layer are soluble in the developer solution and can be removed in a subsequent step (resist stripping). In this subsequent step, the development step, sub-areas of the metal layer on the base substrate are exposed, which can be removed wet-chemically in a further subsequent step, an etching step. The residues of the metal layer remaining after the subsequent complete removal of the resist form the desired conductor structure. If necessary, this can be reinforced in a deposition step, for example, by electroplating a suitable metal.

Conductor tracks produced using at classic method are located on a surface of the base substrate. This can be disadvantageous in the production of MLBs. If a surface of a base substrate provided with conductor tracks is pressed with another base substrate, there is often a subsequent need for control and correction as a result of deviations caused by the pressures and temperatures occurring during pressing. Conductor tracks on the surface of base substrates are particularly exposed to such stresses. The smaller the distances and dimensions of the tracks on the substrate, the greater the corresponding need for control and correction, for example, with regard to existing impedance and signal speed requirements.

DE 102020209767 A1 discloses a method of manufacturing a printed circuit board with a metallic conductor structure that solves this problem. According to that method, a base substrate in the form of a film or sheet is provided, which has a first and a second substrate side, which consists at least partially of an electrically non-conductive organic polymer material and in which the first substrate side is covered with a cover metal layer. To remove the cover metal layer in certain areas, a mask layer of titanium or zinc oxide is applied to the cover metal layer and then removed in certain areas by a laser so that the first substrate side is divided into a first sub-area, in which the first substrate side is covered only with the cover metal layer, and into at least one second sub-area, in which the first substrate side is covered with the cover metal layer and the mask layer. After removal of the cover metal layer in the at least one first sub-area, the first substrate side is subjected to a plasma, with the aid of which the polymer material is removed in the at least one first sub-area, forming at least one recess. The resulting at least one recess is filled with a filler metal, followed by complete removal of the covering metal layer and the mask layer in the at least one second sub-area, forming the desired conductor structure.

The disadvantage of that method is that metal ions are released from the mask layer during plasma treatment, which can be deposited in the resulting recesses. This can lead to undesirable effects.

It could therefore be helpful to develop a method for the manufacture of printed circuit boards with which the problems described can be avoided or at least reduced.

### SUMMARY

We thus provide a method of manufacturing a printed circuit board with a metallic conductor structure comprising a. to i.:
a. provision of a base substrate in the form of a film or sheet with a first substrate side and a second substrate side, which consists at least partially of an electrically non-conductive organic polymer material,
b. cover the first substrate side with a resist,
c. partially removing the resist so that the first substrate side is divided into at least a first subarea in which the first substrate side is still covered with the resist, and at least a second sub-area in which the first substrate side is free of the resist,
d. after partial removal of the resist in the at least one second sub-area, exposing the first substrate side to a plasma, with the aid of which the polymer material in the at least one second sub-area is removed, forming at least one elongate, channel-like recess,
e. metallizing the first substrate side, preferably including the first sub-area and the at least one recess formed, and
f. planarizing the first substrate side, if necessary under removal the metallization in the first sub-area, and retaining the at least one elongated, channel-like recess formed, whereby
g. the resist is a photoresist or a resist made of a laser-removable polymer material,
h. the resist in the first sub-area is completely or at least almost completely removed by the plasma treatment in step d, and
i. the resist is applied to the first substrate side in a thickness that ensures that the desired depth of the elongate channel-like recess in d. is achieved before significant ablation of the first substrate side by the plasma in the first sub-area occurs.

The advantage associated with the process is significant. The use of a metallic mask layer is avoided and, accordingly, the problem of metal ions being deposited in recesses to be formed cannot occur. Steps of forming and removing the mask layer are completely eliminated. Furthermore, masking is not required during metallization since metallized areas outside the at least one recess can also be removed during subsequent planarization.

The at least one recess can be either holes or dot-shaped or elongated, channel-like recesses in which metallic conductor paths can be formed.

In the above context, “almost” means that after the plasma treatment the resist has less than 10% of its original thickness before the start of the etching process and/or no longer covers the entire surface of the first sub-area after the plasma treatment.

The at least one elongated, channel-like recess preferably has a depth of 5 μm to 60 μm. It is further preferred that the elongated, channel-like recesses have a width in of 1 μm to 100 μm.

Preferably, the method additionally comprises at least one of a. and b.:
a. the resist is applied in a thickness sufficient to protect the first substrate side from ablation by the plasma when the first substrate side is exposed to the plasma in the first sub-area, and
b. the resist is applied in a thickness in a ratio of 1.4:1 to 0.6:1 to the desired depth of the elongated, channel-like recess.

The plasma treatment not only removes the polymer material of the base substrate. Rather, the resist is also attacked by the plasma in parallel with the base substrate. The resist thus preferably serves as a kind of sacrificial material, which makes it easier to run the plasma process even without a metallic mask layer.

The polymer material of the base substrate is preferably a thermoplastic polymer material, preferably selected from the group comprising polyimide (either pure polyamide or a blend of a polyimide resin with an epoxy resin), polyamide, Teflon, polyester, polyphenylene sulfide, polyoxymethylene, polyether ketone, cyanate ester, and a mixture of bismaleimides, epoxy, acrylate, PPE (polyphenylene oxide).

The base substrate is preferably a film or sheet made of a polymer material, in particular one of the polymer materials mentioned.

The thickness of the resist can also be selected so that the resist is almost completely or completely removed. Residues of the resist or a surface of the first substrate side that has been slightly attacked by the plasma in the first sub-area can also be removed during subsequent planarization of the first substrate side. In some examples, however, it is preferred that the first sub-area is covered and protected by the resist during the entire plasma treatment.

In these examples, the thickness of the resist is therefore selected as a function of the required depth of the at least one recess such that a layer of resist is still present on the surface when the desired etching depth is reached.

Typically, the resist is applied in a thickness of 8 μm to 150 μm.

In accordance with this, preferably, the method is characterized by a:
a. metallization of the first substrate side, preferably including the first sub-area and the at least one recess formed, takes place immediately after the plasma treatment.

In this example, “directly” means that metallization takes place without prior removal of the resist.

If necessary, residual residues are removed in the usual way, typically by wet chemical means.

With regard to the resist, the method is preferably characterized by at least one of a. and b:
a. the resist is exposed for partial removal, followed by removal of the exposed or the unexposed areas, and
b. the resist is removed by laser ablation in the second sub-area.

Preferably a. and b. are realized in combination with each other.

All organic photoresists known in PCB production can be used as photoresists. These may differ in their sensitivity to the plasma and may therefore be removed by the plasma at different rates. However, the removal rate can be easily determined experimentally, making it easy to adjust the thickness of the resist accordingly.

If the partial removal of the resist is performed by laser ablation, it may be preferable to form the resist from a non-photosensitive polymer. In this context, resists made of polyamide or epoxy resin are particularly suitable. However, all polymer materials that can be removed from a surface by a laser are suitable.

Removal of polymer layers using laser ablation is state of the art and requires no further explanation.

Further preferably, the method is characterized by a:
a. after metallization, a conductor structure is galvanically built up in the at least one recess formed.

The galvanic build-up of the conductor structure is preferably carried out by electrochemical deposition. Particularly preferred is the filling by a so-called via-filling or trench-filling process, which enables the deposition to take place primarily in the at least one recess while simultaneously minimizing unwanted deposition on the first substrate side.

In principle, electroplating can also be carried out after planarization. However, it is preferably carried out before planarization.

The conductor track is preferably made of copper or doped copper. However, it is also possible to construct the conductor track from other metals such as silver, or an alloy such as a chromium-nickel alloy. All metals and alloys that can be used to produce conductor track structures on printed circuit boards can be considered.

Preferably, the metallization serves the purpose of imparting electrical conductivity to the first substrate side and thus preparing it for the subsequent electroplating of the conductor structure, for example, to be able to position a cathodic contact there for subsequent electrochemical deposition. In this example, the metallization is preferably formed as a thin layer with a thickness in the nanometer range, while the subsequently formed conductor structure preferably has a thickness in the one or two-digit μm range.

For metallization, the first substrate side can, for example, be sputtered with metal ions such as copper ions. Alternatively, the metallization can be carried out wet-chemically or by an alternative physical vapor deposition (PVD) or chemical vapor deposition (CVD).

However, particularly in wet-chemical formation of the metallization, it can also be formed in a layer thickness that makes a separate subsequent construction of a conductor structure superfluous. In this example, the metallization is preferably formed such that it fills the at least one recess and also covers the first sub-area. In these areas, the metallization can be removed during planarization.

Preferably, a layer of copper or a copper alloy is formed during metallization. In wet-chemical metallization, the metallization is carried out, for example, by depositing copper from a solution.

Metallization by physical and chemical vapor deposition and the production of metal layers by wet-chemical coating processes or sputter deposition are state of the art and require no further explanation.

Planarization is preferably carried out by polishing or grinding, in particular by chemical mechanical polishing or chemical mechanical planarization (CMP). These procedures are also state of the art and require no further explanation.

The primary aim of planarization is to level the first substrate side such that it does not have any conductor tracks protruding from the surface. Instead, the conductor structure is preferably completely recessed in the at least one recess.

Preferably, conductor structures formed according to the process are coated with a solder resist to protect them. Free contacts can be coated with a precious metal such as gold, silver or platinum.

The method may be used to construct a multilayer printed circuit board. The conductor structure obtained in accordance with the steps described above forms a first conductor structure in this multilayer printed circuit board, which can be connected to further conductor structures in the printed circuit board if necessary. A further conductor structure can, for example, be formed on or in the second substrate side of the base substrate.

Particularly preferably, the method is characterized by at least one of features a. to d:
a. the base substrate comprises fillers, in particular dielectric fillers, in particular ceramic filler particles,
b. the base substrate is a plastic film with the fillers, in particular a plastic film in which the ceramic filler particles are embedded,
c. the fillers have an average particle size (d50)<1 μm, and
d. the polymer material of the base substrate is preferably a thermoplastic polymer material, preferably selected from the group comprising polyimide (either pure polyamide or a blend of a polyimide resin with an epoxy resin), polyamide, Teflon, polyester, polyphenylene sulfide, polyoxymethylene, polyether ketone, cyanate ester, and a mixture of bismaleimides, epoxy, acrylate, PPE (polyphenylene oxide).

Preferably, a. and b., in particular also a. to c., particularly preferably also a. to d., are realized in combination with one another.

If necessary, the base substrate can comprise fillers, in particular dielectric fillers. For example, the base substrate can be a film made of one of the polymer materials mentioned, in which silicon dioxide particles are embedded.

Metal or semi-metal oxides (in addition to silicon dioxide, in particular aluminum oxide, zirconium oxide or titanium oxide) and other ceramic fillers (in particular silicon carbide or boron nitride or boron carbide) are particularly suitable as dielectric fillers. Silicon can also be used if necessary.

The fillers are preferably present in particulate form, in particular with an average particle size (d50) in the nanometer range (<1 μm).

For easier handling, the base substrate can be applied to a carrier or an auxiliary substrate, for example made of glass or aluminum, for processing.

Further preferably, the method comprises at least one of a. and b.:
a. a process gas from the group comprising O₂, H₂, N₂, argon, helium, CF₄, C₃F₈, CHF₃ and mixtures of the aforementioned gases such as O₂/CF₄ is used to provide the plasma, and
b. the plasma is applied at a temperature of minus 15° C. to 200° C., preferably minus 15° C. to 80° C.

Preferably, a. and b. are realized in combination with each other.

Particularly preferably, the process gas used to provide plasma comprises at least one of the reactive gases from the group comprising CF₄, C₃F₈ and CHF₃.

Etching using a plasma is also state of the art. Plasma etching uses process gases that can transfer the material to be etched into the gas phase. The gas enriched with the etched material is pumped out and fresh process gas is supplied. In this way, continuous removal is achieved.

An inductively coupled plasma (ICP plasma) is particularly preferred for example, generated by an ICP generator with DC bias.

The process gases mentioned immediately above are particularly suitable for etching the preferred polymer materials mentioned above.

Particularly preferably, the plasma is used as part of an anisotropic etching process. Ideally, ions from the plasma are accelerated perpendicular to the surface of the substrate to be etched. The accelerated ions ensure physical sputter removal.

Particularly suitable as an anisotropic etching process are reactive ion etching (RIE) and reactive ion beam etching (RIBE).

Accordingly, preferably, the method is characterized by at least one of a. to c:
a. the plasma is used as part of an anisotropic etching process,
b. in the anisotropic etching process, ions of the plasma are accelerated perpendicular to the first substrate side and/or the top side, and
c. the process gas used for plasma supply comprises at least one of the reactive gases from the group with CF₄, C₃F₈ and CHF₃.

Preferably, a. and b., particularly preferably a. to c., are realized in combination with one another.

Surprisingly, we found that the presence of the above-mentioned particulate fillers has a beneficial effect on the result of material removal by the plasma. This applies in particular to the combined use of
a. a process gas comprising at least one of the reactive gases from the group comprising CF₄, C₃F₈ and CHF₃, in particular a mixture of at least one of these gases with O₂, H₂, N₂, argon and/or helium, and
b. a plastic film as a base substrate, which comprises at least one ceramic filler with a particle size (d50)<1 μm.

It is particularly preferred that the plastic film comprises at least one ceramic filler with a particle size (d50)<1 μm and at the same time is free of particles with a particle size >10 μm, preferably >5 μm, particularly preferably >2 μm, especially >1 μm. With this preferred particle size, when using the process gases, it is possible to adjust the etching speed such that the filler particles and the polymer components of the plastic film are etched at approximately the same speed so that no particulate components are released from the film during etching that could interfere with further processing of the film.

This is particularly possible when at least one filler from the group comprising silicon dioxide, aluminum oxide, zirconium oxide, titanium oxide, silicon carbide, boron nitride and boron carbide is used, and when films based on one of said thermoplastic polymer materials are used at the same time, in particular in films made of polyimide (either pure polyimide or a blend of a polyimide resin with an epoxy resin), polyamide, Teflon, polyester, polyphenylene sulphide, polyoxymethylene, polyether ketone, cyanate ester, or a mixture of bismaleimides, epoxy, acrylate, PPE (polyphenylene oxide).

According to the process, printed circuit boards can be produced with the highest resolution in the μm range, with less effort and lower production costs and at the same time with a higher yield than the state of the art allows.

The fact that the conductor structures are recessed in the base substrate has a positive effect in the manufacture of MLBs, particularly in the sequential structure described. The pressures acting on the conductor structures when base substrates and insulation layers are pressed together are comparatively low, which has a positive effect with regard to existing impedance and signal speed requirements. The fact that plasma etching can be used to form channels with extremely high accuracy also has a positive effect in this respect.

Such channels can also be formed using a laser. In contrast, plasma etching offers the advantage that all channels and other recesses can be formed simultaneously and in a single step, which is generally many times faster and more cost-effective. Furthermore, higher resolutions can be achieved using plasma etching.

### BRIEF DESCRIPTION OF THE DRAWING

Further features, details and advantages are apparent from the claims and the summary, the wording of both of which is made the content of the specification by reference, from the following description of preferred examples and from the drawing.

The FIGURE schematically illustrates the step sequence of a preferred example of the method.

### DETAILED DESCRIPTION

In a method according to the FIGURE, to form a printed circuit board 100 with a metallic conductor structure 101, a base substrate 102 made of an electrically non-conductive polymer material is provided in a step A, the first substrate side 102a of which is covered with a resist 103.

In a step B, the resist 103 is partially removed so that the first substrate side 102a is divided into at least a first sub-area 102b, in which the first substrate side 102a is still covered with the resist 103, and into at least a second sub-area 102c, in which the first substrate side 102a is free of the resist 103.

In a step C, the first substrate side 102a is exposed to a plasma. This results in removal of the polymer material in the at least one second sub-area 102c, forming the elongate, channel-like recesses 104. At the same time, the plasma also attacks the resist 103. In the variant shown, this is provided with a layer thickness that is sufficient for the first sub-area 102b to still be covered by a thin layer of the resist 103 after completion of the plasma treatment. This is then removed by wet chemical means, the result is shown in D.

In an alternative, the resist 103 is applied in a thickness which is in a ratio of 1.4:1 to 0.6:1 to the desired depth of the elongated, channel-like recess, and removed by the plasma treatment to such an extent that subsequent wet-chemical removal of the resist is no longer necessary. As a result, the plasma treatment can be immediately followed by the metallization described below (step E).

In step E, metallization of the first substrate side 102a is performed by wet chemical deposition, which is performed such that the entire substrate side 102a is covered with the deposited metal, including the recesses. Subsequent planarization removes excess metal on the first substrate surface 102a and exposes the conductor structure 101, see step F. The conductor structure 101 comprises elongated channel-like recesses filled with the metal deposited in step E.

If necessary, the metallization in step E can comprise several individual steps.

1.-8. (canceled)

9. A method of manufacturing a printed circuit board having a metallic conductor structure comprising:
a. providing a base substrate in a film or sheet having a first substrate side and a second substrate side, which consists at least partly of an electrically non-conductive organic polymer material,
b. covering the first substrate side with a resist,
c. partially removing the resist, so that the first substrate side is divided into at least a first sub-area, in which the first substrate side is still covered with the resist, and into at least a second sub-area, in which the first substrate side is free of the resist,
d. after partial removal of the resist in the at least one second sub-area, applying a plasma to the first substrate side such that the polymer material in the at least one second sub-area is removed, and thereby forming at least one elongate, channel-like recess,
e. applying a metallization to the first substrate side, and
f. planarizing the first substrate side, optionally with removal of the metallization in the first sub-area, and with retention of the formed at least one elongate, channel-like recess,
wherein
g. the resist is a photoresist or a resist made of a laser-removable polymer material,
h. the resist in the first sub-area is completely or at least almost completely removed by the plasma treatment in d., and
i. the resist is applied to the first substrate side in a thickness that ensures that a desired depth of the elongate channel-like recess in d. is achieved before significant ablation of the first substrate side by the plasma in the first sub-area occurs.

10. The method according to claim 9, further comprising:
a. applying the resist in a thickness ratio of 1.4:1 to 0.6:1 to the desired depth of the elongated, channel-like recess.

11. The method according to claim 9, wherein the metallization according to e. is carried out immediately after the plasma treatment.

12. The method according to claim 9, when at least one of:
a. the resist is exposed for partial removal, followed by removal of the exposed or unexposed sub-areas, and
b. the resist is removed by laser ablation in the second sub-area.

13. The method according to claim 9, wherein at least one of:
a. the base substrate contains ceramic filler particles,
b. the fillers have an average particle size (d50)<1 μm, and
c. the polymer material of the base substrate is a thermoplastic polymer material selected from the group consisting of polyimide (either pure polyamide or a blend of a polyimide resin with an epoxy resin), polyamide, Teflon®, polyester, polyphenylene sulfide, polyoxymethylene, polyether ketone, cyanate ester, and a mixture of bismaleimides, epoxy, acrylate, and PPE (polyphenylene oxide).

14. The method according to claim 9, further comprising after metallization, a conductor structure is galvanically built up in the at least one recess.

15. The method according to claim 9, wherein:
a. in d., a process gas is used which comprises at least one of the reactive gases from the group comprising CF₄, C₃F₈ and CHF₃, of a mixture of at least one of these gases with O₂, H₂, N₂, argon and/or helium, and
b. a plastic film comprising at least one ceramic filler with a particle size (d50)<1 μm is used as the base substrate.

16. A printed circuit board with a metallic conductor structure, manufactured according to a method according to claim 9.
